(19) United States
(12) Patent Application Publication
(10) Pub. No.: US 2026/0086145 A1
(43) Pub. Date: Mar. 26, 2026

(54) CHIP, SYSTEM, AND METHOD FOR BOUNDARY TESTING

(71) Applicant: REALTEK SEMICONDUCTOR CORP., Hsinchu (TW)

(72) Inventor: Szu-Yang Chang, Hsinchu (TW)

(73) Assignee: REALTEK SEMICONDUCTOR CORP., Hsinchu (TW)

(21) Appl. No.: 19/317,312

(22) Filed: Sep. 3, 2025

(30) Foreign Application Priority Data
Sep. 20, 2024 (TW) 113135845

(51) Int. Cl. G01R 31/28

(52) U.S. Cl. CPC G01R 31/2884

(57) ABSTRACT

A chip with boundary testing includes two circuit groups. During a first shift-in period, a first circuit group receives a first test input, and a first boundary circuit of the first circuit group has first boundary data after receiving the first test input. During a first calculation period after the first shift-in period, a second boundary circuit of a second circuit group captures the first boundary data, and the second circuit group performs circuit calculation according to the first boundary data to generate a first test output. During a second shift-in period after the first calculation period, a second main circuit of the second circuit group outputs the first test output.

### CROSS-REFERENCE TO RELATED APPLICATION

This non-provisional application claims priority under 35 U.S.C. § 119 (a) to patent application No. 113135845 filed in Taiwan, R.O.C. on Sep. 20, 2024, the entire contents of which are hereby incorporated by reference.

### BACKGROUND

### Technical Field

The present invention relates to a testing technology, and in particular, to a chip, system, and method for boundary testing.

### Related Art

Generally, when a circuit of a chip is overly large, the entire circuit of the chip is divided into a plurality of circuit groups for testing, to avoid excessive power consumption during the testing.

However, when the circuit groups are tested separately, a boundary circuit connected to other circuit groups in each circuit group cannot be tested. In order to be able to test the boundary circuit of the circuit group, it may take time to select a boundary circuit from the circuit group, and an additional circuit may be added to test the selected boundary circuit.

### SUMMARY

According to an embodiment, a chip with boundary testing is provided, including a first circuit group and a second circuit group. The first circuit group includes a first main circuit and a first boundary circuit. The first boundary circuit is coupled to the first main circuit. The second circuit group includes a second main circuit and a second boundary circuit. The second boundary circuit is coupled to the second main circuit and the first boundary circuit. During a first shift-in period, the first circuit group receives a first test input, and the first boundary circuit has first boundary data after the first circuit group receives the first test input. During a first calculation period after the first shift-in period, the second boundary circuit captures the first boundary data, and the second circuit group performs a circuit calculation according to the first boundary data to generate a first test output. During a second shift-in period after the first calculation period, the second main circuit outputs the first test output.

According to an embodiment, a boundary testing system is provided, including a chip and a test machine, and the test machine is coupled to the chip. The chip includes a first circuit group and a second circuit group. The first circuit group includes a first main circuit and a first boundary circuit. The first boundary circuit is coupled to the first main circuit. The second circuit group includes a second main circuit and a second boundary circuit. The second boundary circuit is coupled to the second main circuit and the first boundary circuit. During a first shift-in period, the test machine outputs a first test input to the first circuit group, so that the first boundary circuit has first boundary data after the first circuit group receives the first test input. During a first calculation period after the first shift-in period, the second boundary circuit captures the first boundary data, and the second circuit group performs a circuit calculation according to the first boundary data to generate a first test output. During a second shift-in period after the first calculation period, the second main circuit outputs the first test output to the test machine, and the test machine compares the first test output with a first expected result to generate a first comparison result.

According to an embodiment, a boundary testing method applicable to a chip is provided, including: during a first shift-in period, outputting a first test input to a first circuit group of the chip, so that a first boundary circuit of the first circuit group has first boundary data after receiving the first test input; during a first calculation period after the first shift-in period, using a second boundary circuit of a second circuit group of the chip to capture the first boundary data, and using a second main circuit and the second boundary circuit of the second circuit group to perform circuit calculation according to the first boundary data to generate a first test output, where the second main circuit is coupled to the second boundary circuit; and during a second shift-in period after the first calculation period, using the second main circuit to output the first test output, and comparing the first test output with a first expected result to generate a first comparison result.

In summary, in the chip, the boundary testing system, and the boundary testing method according to any one of the embodiments, the boundary circuits are tested by dynamically switching the circuit groups. In this way, there is no need to add an additional circuit for testing the boundary circuits, and there is also no need to spend time selecting the boundary circuit to be currently tested from the circuit groups. In addition, in the chip, the boundary testing system, and the boundary testing method according to any one of the embodiments, all circuit units inside the chip can operate according to an original grouping manner, while maintaining a testing relationship between the circuit groups.

The detailed features and advantages of the present invention are described in detail below in the implementation. The content is sufficient to enable anyone familiar with the relevant art to understand the technical content of the present invention and implement it according to the content disclosed in this specification, the patent scope, and the drawings. Anyone familiar with the relevant art can easily understand the relevant purposes and advantages of the present invention.

### BRIEF DESCRIPTION OF THE DRAWINGS

FIG. 1 is a schematic diagram of an embodiment of a boundary testing system;

FIG. 2 is a schematic diagram of an embodiment of a chip in FIG. 1;

FIG. 3 is a schematic flowchart of an embodiment of a boundary testing method;

FIG. 4 is a schematic diagram of an example of the chip in FIG. 2 during a first shift-in period;

FIG. 5 is a schematic diagram of an example of the chip in FIG. 2 during a first calculation period;

FIG. 6 is a schematic diagram of an example of the chip in FIG. 2 during a second shift-in period;

FIG. 7 is a schematic diagram of an example of the chip in FIG. 2 during a second calculation period;

FIG. 8 is a schematic diagram of another embodiment of the chip in FIG. 1;

FIG. 9 is a schematic flowchart of another embodiment of the boundary testing method;

FIG. 10 is a schematic diagram of an example of the chip in FIG. 8 during a first shift-in period; and

FIG. 11 is a schematic diagram of an example of the chip in FIG. 8 during a first calculation period.

### DETAILED DESCRIPTION

To make the objectives, features, and advantages of the embodiments of the present invention clearer and easy to understand, detailed descriptions are given below with reference to the accompanying drawings.

It should be understood that the words “comprise” and “include” used in this specification are used to indicate the presence of specific technical features, values, method steps, processes, elements and/or components, but it does not exclude that there may be more technical features, numerical values, method steps, processes, elements, components, or any combination of the above.

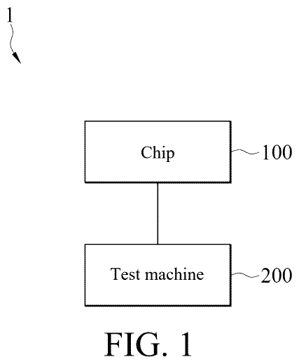

FIG. 1 is a schematic diagram of an embodiment of a boundary testing system. Refer to FIG. 1. The boundary testing system 1 includes a chip 100 and a test machine 200, and the test machine 200 is coupled to the chip 100.

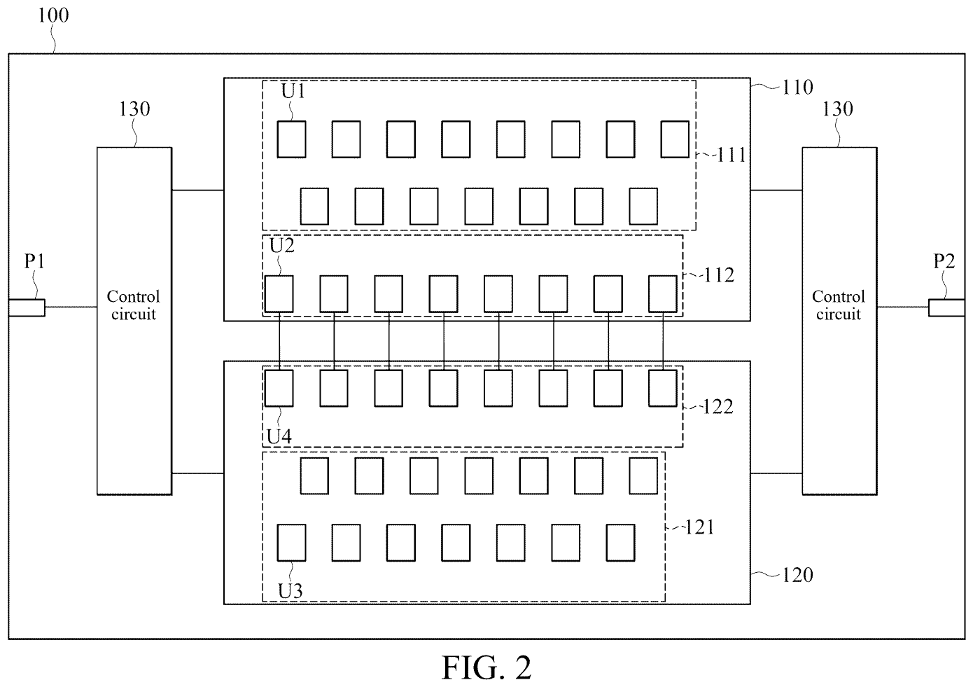

FIG. 2 is a schematic diagram of an embodiment of a chip in FIG. 1. Refer to FIG. 2. The chip 100 includes at least two circuit groups (for example, a first circuit group 110 and a second circuit group 120). Each circuit group includes a main circuit and a boundary circuit coupled to each other, and is coupled to a boundary circuit of the other circuit group through a boundary circuit thereof. For clear description, two circuit groups are taken as an example. The two circuit groups are respectively referred to the first circuit group 110 and the second circuit group 120. The first circuit group 110 and the second circuit group 120 are related to each other in terms of circuit calculation.

In some embodiments, the first circuit group 110 includes a first main circuit 111 and a first boundary circuit 112, and the first boundary circuit 112 is coupled to the first main circuit 111 and a second boundary circuit 122. The second circuit group 120 includes a second main circuit 121 and the second boundary circuit 122, and the second boundary circuit 122 is coupled to the second main circuit 121 and the first boundary circuit 112.

In some embodiments, the first main circuit 111 includes a plurality of circuit units U1, and the first boundary circuit 112 includes a plurality of circuit units U2. The second main circuit 121 includes a plurality of circuit units U3, and the second boundary circuit 122 includes a plurality of circuit units U4. In this way, each circuit unit U1/U2/U3/U4 may be a circuit same as or different from the other circuit units U1/U2/U3/U4. In this way, the main circuit is composed of circuit units that are located inside a circuit group and cannot directly communicate with other circuit groups (that is, each circuit unit has no connection path to couple to other circuit groups), and the boundary circuit is composed of circuit units that are located at a boundary of a circuit group and can directly communicate with other circuit groups (that is, each circuit unit is coupled to the other circuit group with a boundary path). In some implementations, each circuit unit U1/U2/U3/U4 may be, but is not limited to, a D-type flip-flop (DFF).

In some embodiments, the plurality of circuit units U1, U2, U3, and U4 there have a corresponding calculation relationship, for example, but not limited to, addition and subtraction, according to a design requirement of the chip 100. Each circuit unit U1 of the first main circuit 111 may have a calculation relationship with the other circuit units U1 of the first main circuit 111 and/or the circuit units U2 of the first boundary circuit 112, but have no calculation relationship with the circuit units U3/U4 of the second circuit group 120. Each circuit unit U3 of the second main circuit 121 may have a calculation relationship with the other circuit units U3 of the second main circuit 121 and/or the circuit units U4 of the second boundary circuit 122, but have no calculation relationship with the circuit units U1/U2 of the first circuit group 110. In addition, the circuit units U2 of the first boundary circuit 112 have a calculation relationship with the circuit units U4 of the second boundary circuit 122. For example, each circuit unit U2 of the first boundary circuit 112 outputs data to a circuit unit U4 of the second boundary circuit 122 to perform circuit calculation, or receives data outputted by a circuit unit U4 of the second boundary circuit 122 to perform circuit calculation. In other words, the first circuit group 110 and the second circuit group 120 are related circuit groups in terms of circuit calculation, and the first boundary circuit 112 and the second boundary circuit 122 are related circuits in terms of circuit calculation. In this way, to express concisely, the calculation relationship between the circuit units U2 of the first boundary circuit 112 and the circuit units U4 of the second boundary circuit 122 is simply drawn in a straight line, and a calculation relationship between the other circuit units are omitted and not shown.

In some embodiments, the chip 100 may further include at least one test pin configured to connect to an external test machine 200. In the following, two test pins P1 and P2 are used as an example for description, but the number is not limited to this. In addition, the chip 100 may further include a control circuit 130, and the control circuit 130 is coupled between the first circuit group 110, and the test pins P1 and P2, and between the second circuit group 120 and the test pins P1 and P2. In this way, the control circuit 130 may be configured to control operation of the first circuit group 110 and the second circuit group 120. In addition, the control circuit 130 may be further configured to control a connection relationship between the test pins P1 and P2 and the first circuit group 110 and between the test pins P1 and P2 and the second circuit group 120. In some embodiments, the control circuit 130 is configured to control a connection relationship between the first main circuit 111 of the first circuit group 110 and the test pins P1 and P2, and control a connection relationship between the second main circuit 121 of the second circuit group 120 and the test pins P1 and P2.

It should be noted that, for clear description of this application, FIG. 2 of this application is a simplified schematic diagram, which only shows elements related to the present invention. A person skilled in the art should understand that the chip 100 may further include other elements configured to provide specific functions.

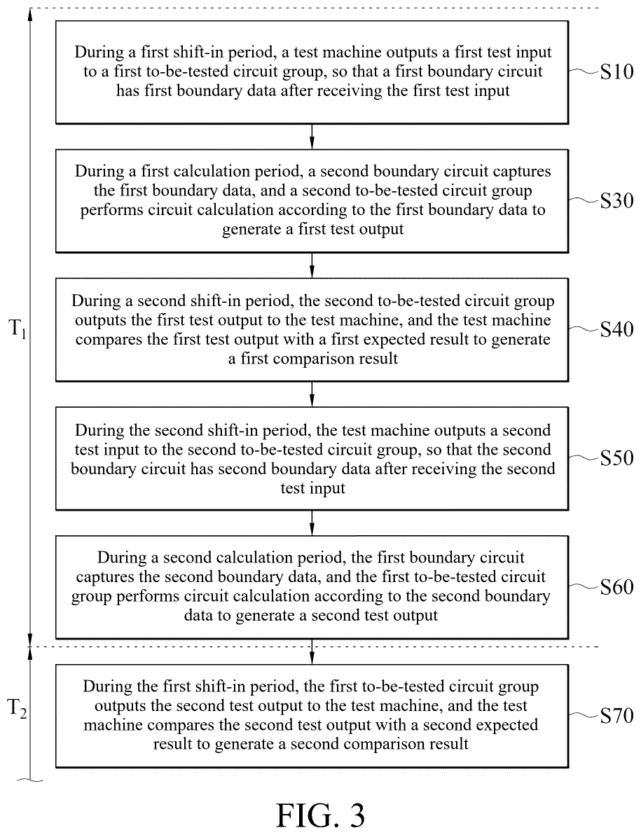

FIG. 3 is a schematic flowchart of an embodiment of a boundary testing method. Refer to FIG. 1 to FIG. 3. In some embodiments, the boundary testing system 1 includes a plurality of test cycles connected in sequence, and each test cycle may include a first shift-in period, a first calculation period, and a second shift-in period that are configured in sequence.

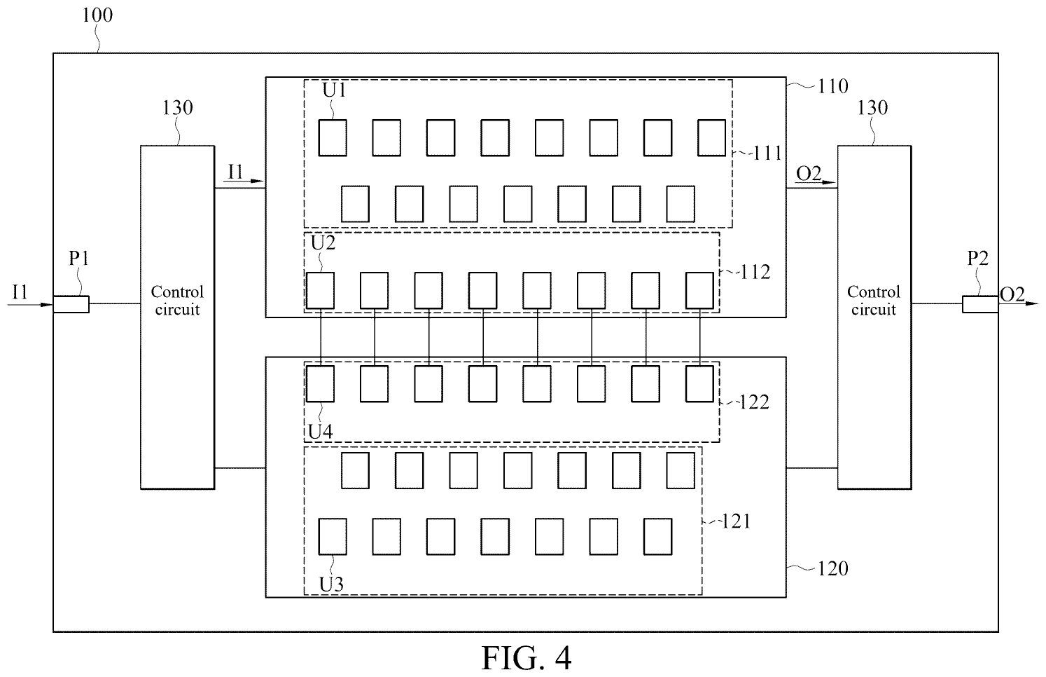

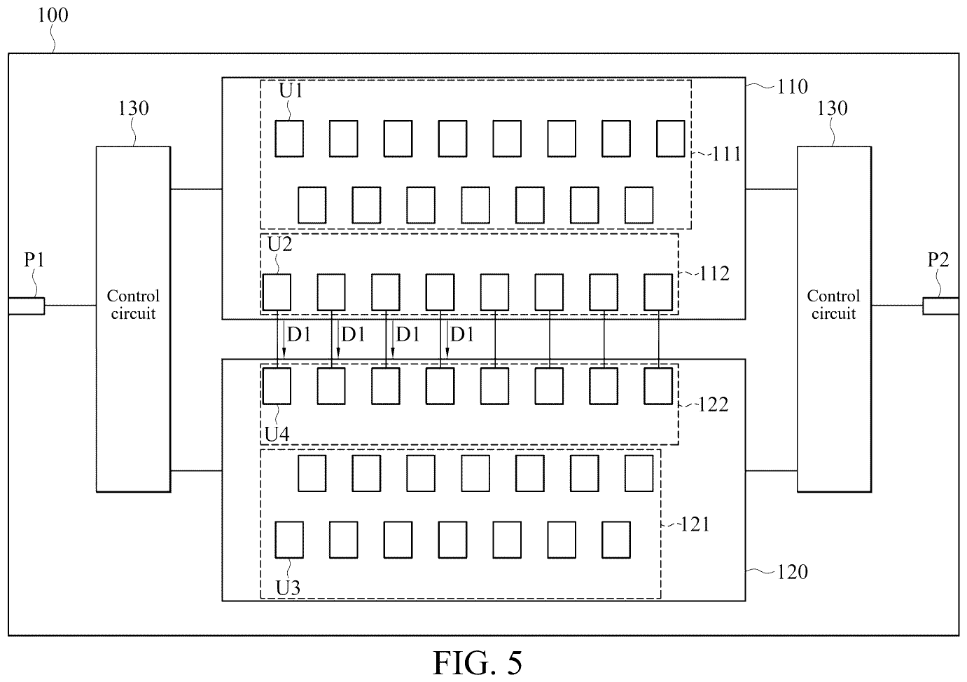

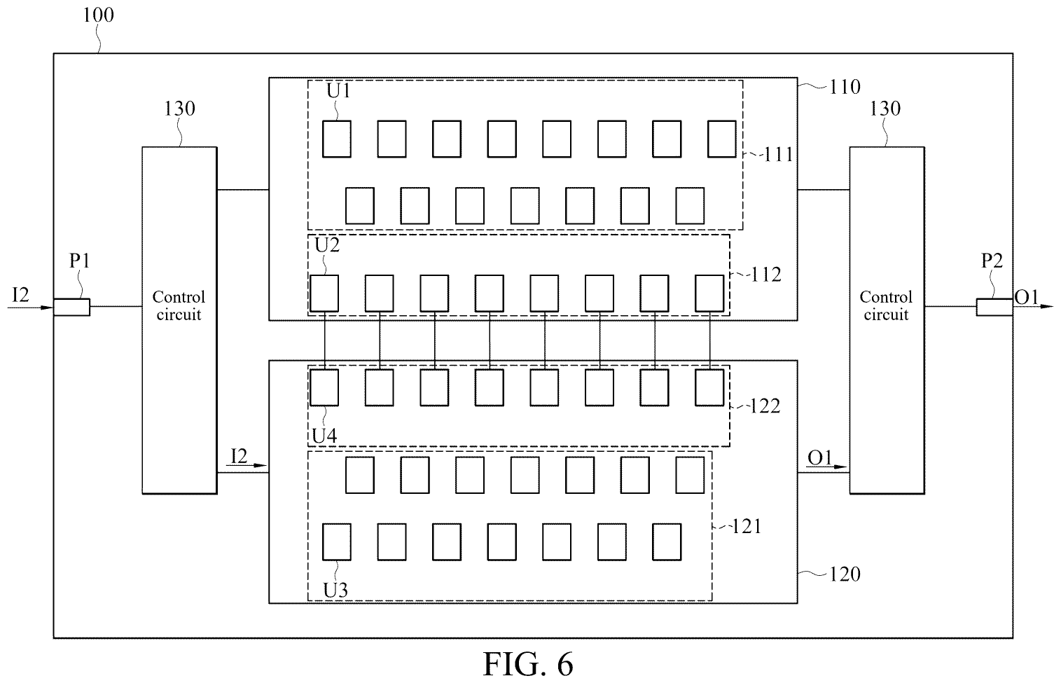

FIG. 4 is a schematic diagram of an example of the chip in FIG. 2 during a first shift-in period. FIG. 5 is a schematic diagram of an example of the chip in FIG. 2 during a first calculation period. FIG. 6 is a schematic diagram of an example of the chip in FIG. 2 during a second shift-in period. Refer to FIG. 3 to FIG. 6. During the first shift-in period, the test machine 200 of the boundary testing system 1 outputs a first test input I1 to the first circuit group 110 of the chip 100, so that the first boundary circuit 112 of the first circuit group 110 has first boundary data D1 after receiving the first test input I1 (step S10).

Specifically, as shown in FIG. 4, during the first shift-in period, the test machine 200 generates and outputs the first test input I1 to the test pin P1 of the chip 100. The control circuit 130 of the chip 100 disconnects the second circuit group 120 from the test pin P1, and establishes a connection between the test pin P1 and the first circuit group 110. In addition, the control circuit 130 causes the second circuit group 120 to not operate, and causes the first circuit group 110 to operate, so that the first circuit group 110 may receive the first test input I1 through the test pin P1. After the first circuit group 110 receives the first test input I1, the first boundary circuit 112 has the first boundary data D1. In this way, the first boundary data D1 refers to data subsequently outputted to the second boundary circuit 122 of the second circuit group 120, as shown in FIG. 5.

In some embodiments, the first circuit group 110 operates according to a first clock signal, and the second circuit group 120 operates according to a second clock signal. Therefore, in some embodiments, in step S10, the control circuit 130 may cause the second circuit group 120 to not operate by stopping inputting the second clock signal to the second circuit group 120, for example, but not limited to, disconnecting the second circuit group 120 from a clock source used to generate the second clock signal. In some embodiments, an on period (for example, a logic “1” period) of the first clock signal and an on period (for example, a logic “1” period) of the second clock signal may be mutually exclusive. In other words, when the first circuit group 110 operates, the second circuit group 120 stops operation. When the second circuit group 120 operates, the first circuit group 110 stops operation. In some embodiments, the second circuit group 120 that stops operation stops all circuits that the second circuit group 120 has, and maintains data before the stop (that is, maintain an original value). Similarly, the first circuit group 110 that stops operation also stops all circuits that the first circuit group 110 has, and maintains data before the stop (that is, maintain an original value).

Subsequently, during the first calculation period, the second boundary circuit 122 of the second circuit group 120 captures the first boundary data D1 of the first boundary circuit 112, and the second circuit group 120 performs circuit calculation according to the first boundary data D1 to generate a first test output O1 (step S30).

Specifically, as shown in FIG. 5, during the first calculation period, the control circuit 130 of the chip 100 causes the first circuit group 110 to not operate, and causes the second circuit group 120 to operate. In this way, the circuit unit U4 that needs the first boundary data D1 for circuit calculation in the second boundary circuit 122 of the second circuit group 120 captures the first boundary data D1 of the first boundary circuit 112, and the second main circuit 121 and the second boundary circuit 122 of the second circuit group 120 perform circuit calculation according to currently saved data and the first boundary data D1 to generate the first test output O1.

In some embodiments, the currently saved data of the second circuit group 120 during the first calculation period may be data that the second circuit group 120 has after receiving a second test input 12 during the second shift-in period of a previous test cycle. In some other embodiments, when the test cycle is a first test cycle of an entire test process, a pre-shift-in period may be further included before the first calculation period. During the pre-shift-in period, the test machine 200 generates and outputs the second test input 12 to the test pin P1 of the chip 100. The control circuit 130 of the chip 100 disconnects the test pin P1 from the first circuit group 110, and establishes the connection between the test pin P1 and the second circuit group 120. In addition, the control circuit 130 causes the first circuit group 110 to not operate, and causes the second circuit group 120 to operate, so that the second circuit group 120 may receive the second test input 12 through the test pin P1. In other words, the currently saved data of the second circuit group 120 during the first calculation period may also be data that the second circuit group 120 has after receiving a second test input 12 during the pre-shift-in period.

In some embodiments, in the first test cycle, the pre-shift-in period may be configured before the first shift-in period or after the first shift-in period.

In some embodiments, during the first calculation period, the test machine 200 may not generate any test input to the test pin P1 of the chip 100, and/or the control circuit 130 of the chip 100 disconnects the test pin P1 from the first circuit group 110 and the second circuit group 120. In addition, during the first calculation period, the control circuit 130 of the chip 100 may further disconnect the test pin P2 from the first circuit group 110 and the second circuit group 120.

Subsequently, during the second shift-in period, the second main circuit 121 of the second circuit group 120 outputs the first test output O1 to the test machine 200, so that the test machine 200 is compared with a first expected result according to the first test output O1 to generate a first comparison result (step S40).

Specifically, as shown in FIG. 6, during the second shift-in period, the control circuit 130 of the chip 100 disconnects the test pin P2 from the first circuit group 110, and establishes the connection between the test pin P2 and the second circuit group 120. In addition, the control circuit 130 causes the first circuit group 110 to not operate, and causes the second circuit group 120 to operate. In this way, the second main circuit 121 of the second circuit group 120 outputs the first test output O1 to the test pin P2, so that the test machine 200 receives the first test output O1 through the test pin P2. Later, the test machine 200 may compare the first test output O1 with the first expected result, to generate the first comparison result.

In some embodiments, when the first comparison result indicates that the first test output O1 is consistent with the first expected result, it indicates that a function of the second circuit group 120 of the chip 100 is normal, and a function of the circuit unit U2 in the first boundary circuit 112 that outputs the first boundary data D1 to the second boundary circuit 122 is normal. When the first comparison result indicates that the first test output O1 is inconsistent with the first expected result, it indicates that functions of the second circuit group 120 of the chip 100 and the circuit unit U2 in the first boundary circuit 112 that outputs the first boundary data D1 to the second boundary circuit 122 may be abnormal. In some embodiments, the test machine 200 may further determine which circuit unit U2/U3/U4 has an error according to the first comparison result.

In some embodiments, during the second shift-in period, the test machine 200 may further output a second test input 12 to the second circuit group 120 of the chip 100, so that the second boundary circuit 122 of the second circuit group 120 has second boundary data D2 after receiving the second test input 12 (step S50).

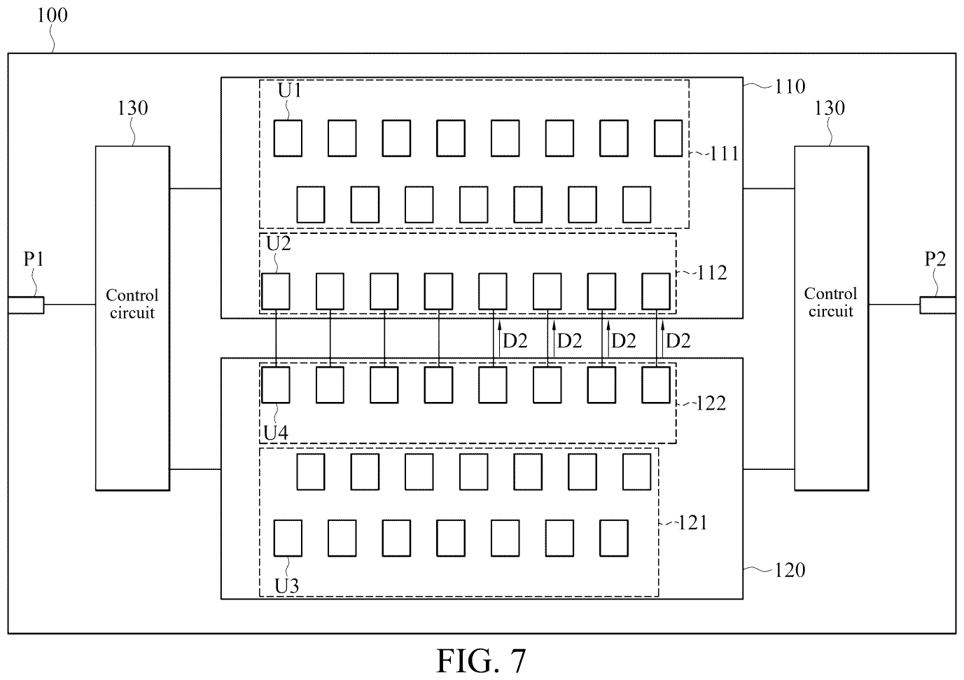

Specifically, during the second shift-in period, the test machine 200 generates and outputs the second test input 12 to the test pin P1 of the chip 100. The control circuit 130 of the chip 100 disconnects the first circuit group 110 from the test pin P1, and establishes the connection between the test pin P1 and the second circuit group 120, so that the second circuit group 120 may receive the second test input 12 through the test pin P1. After the second circuit group 120 receives the second test input 12, the second boundary circuit 122 has second boundary data D2. In this way, the second boundary data D2 refers to data subsequently outputted to the first boundary circuit 112 of the first circuit group 110, as shown in FIG. 7.

In some embodiments, during the second shift-in period, step S40 and step S50 may be performed synchronously. In other words, when the test machine 200 outputs the second test input 12 to the second circuit group 120, the second circuit group 120 synchronously outputs the first test output O1 to the test machine 200.

In some embodiments, each test cycle of the boundary testing system 1 may further include a second calculation period, and the second calculation period is configured after the second shift-in period.

FIG. 7 is a schematic diagram of an example of the chip in FIG. 2 during a second calculation period. Refer to FIG. 3 to FIG. 7. During the second calculation period, the first boundary circuit 112 of the first circuit group 110 captures the second boundary data D2 of the second boundary circuit 122, and the first circuit group 110 performs circuit calculation according to the second boundary data D2 to generate a second test output O2 (step S60).

Specifically, as shown in FIG. 7, during the second calculation period, the control circuit 130 of the chip 100 causes the second circuit group 120 to not operate, and causes the first circuit group 110 to operate. In this way, the circuit unit U2 that needs the second boundary data D2 to perform circuit calculation in the first boundary circuit 112 of the first circuit group 110 captures the second boundary data D2 of the second boundary circuit 122, and the first main circuit 111 and the first boundary circuit 112 of the first circuit group 110 perform circuit calculation according to currently saved data and the second boundary data D2 to generate the second test output O2.

In some embodiments, the currently saved data of the first circuit group 110 during the second calculation period may be data that the first circuit group 110 has after receiving a first test input I1 during the first shift-in period of the test cycle.

In some embodiments, during the second calculation period, the test machine 200 may not generate any test input to the test pin P1 of the chip 100, and/or the control circuit 130 of the chip 100 disconnects the test pin P1 from the first circuit group 110 and the second circuit group 120. In addition, during the second calculation period, the control circuit 130 of the chip 100 may further disconnect the test pin P2 from the first circuit group 110 and the second circuit group 120.

Refer to FIG. 3 and FIG. 4. In some embodiments, when the test cycle T1 has the second calculation period, during the first shift-in period of the test cycle T2 subsequent to the test cycle T1, the first main circuit 111 of the first circuit group 110 further outputs the second test output O2 to the test machine 200, so that the test machine 200 is compared with a second expected result according to the second test output O2 to generate a second comparison result (step S70).

Specifically, as shown in FIG. 4, in step S70, the control circuit 130 of the chip 100 disconnects the test pin P2 from the second circuit group 120, and establishes the connection between the test pin P2 and the first circuit group 110. In addition, the control circuit 130 causes the second circuit group 120 to not operate, and causes the first circuit group 110 to operate. In this way, the first main circuit 111 of the first circuit group 110 outputs the second test output O2 to the test pin P2, so that the test machine 200 receives the second test output O2 through the test pin P2. Subsequently, the test machine 200 may compare the second test output O2 with the second expected result, to generate the second comparison result.

In some embodiments, when the second comparison result indicates that the second test output O2 is consistent with the second expected result, it indicates that a function of the first circuit group 110 of the chip 100 is normal, and a function of the circuit unit U4 in the second boundary circuit 122 that outputs the second boundary data D2 to the first boundary circuit 112 is normal. When the second comparison result indicates that the second test output O2 is inconsistent with the second expected result, it indicates that functions of the first circuit group 110 of the chip 100 and the circuit unit U4 in the second boundary circuit 122 that outputs the second boundary data D2 to the first boundary circuit 112 are abnormal. In some embodiments, the test machine 200 may further determine which circuit unit U1/U2/U4 has an error according to the second comparison result.

In some embodiments, during the first shift-in period (except the first shift-in period in the first test cycle), step S10 and step S70 may be performed synchronously. In other words, when the test machine 200 outputs the first test input I1 to the first circuit group 110, the first circuit group 110 synchronously outputs the second test output O2 to the test machine 200.

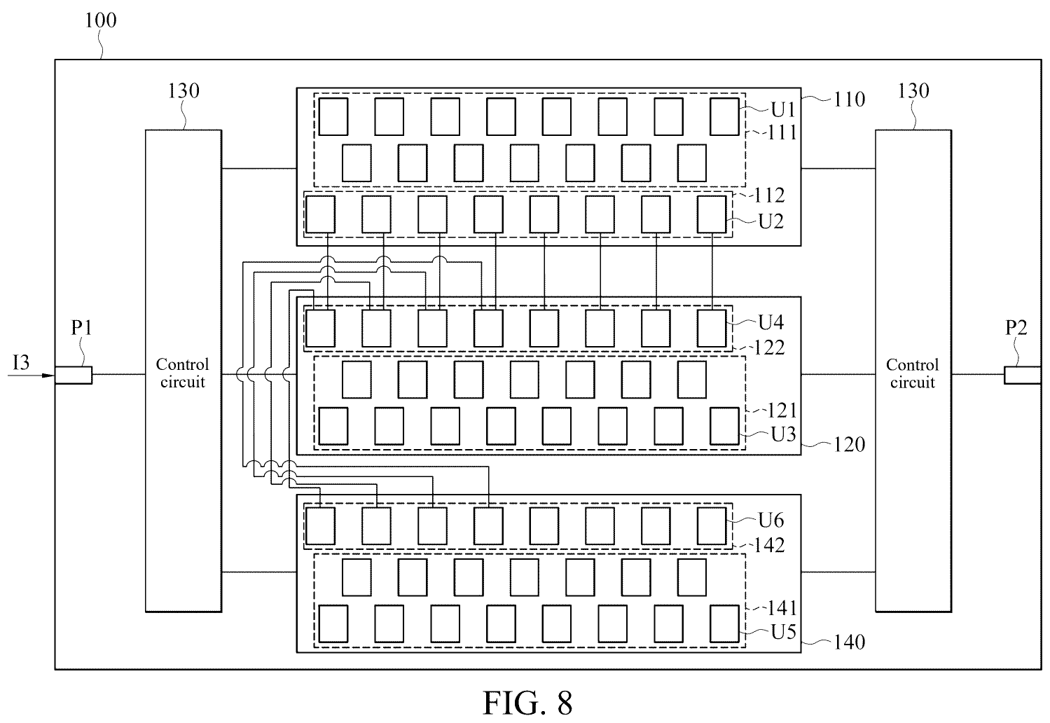

In some embodiments, there may be only one related circuit group of the circuit group, as shown in FIG. 2. In some other embodiments, there may be a plurality of related circuit groups of the circuit group, as shown in FIG. 8. In other words, in the same chip 100, there may be a plurality of circuit groups related to each other in terms of circuit calculation. In the following, the second circuit group 120 is used as an example for description.

FIG. 8 is a schematic diagram of another embodiment of the chip in FIG. 1. Refer to FIG. 8. In some embodiments, the chip 100 may further include a third circuit group 140, and the third circuit group 140 is a related circuit group of the second circuit group 120 in terms of circuit calculation. In other words, in some embodiments, the related circuit group of the second circuit group 120 may include the first circuit group 110 and the third circuit group 140.

In some embodiments, the third circuit group 140 includes a third main circuit 141 and a third boundary circuit 142, and the third boundary circuit 142 is coupled to the third main circuit 141 and the second boundary circuit 122. In addition, the control circuit 130 is coupled to the third circuit group 140, and the third main circuit 141 is coupled between the test pins P1 and P2. In this way, the control circuit 130 may be configured to control operation of the third circuit group 140, and control the connection relationship between the third main circuit 141 and the test pins P1 and P2.

In some embodiments, the third main circuit 141 includes a plurality of circuit units U5, and the third boundary circuit 142 includes a plurality of circuit units U6. In this way, each circuit unit U5/U6 may be a circuit same as or different from the other circuit unit U1/U2/U3/U4/U5/U6. In some implementations, each circuit unit U1/U2/U3/U4/U5/U6 may be, but is not limited to, a D-type flip-flop.

In some embodiments, the calculation relationship between the first circuit group 110 and the third circuit group 140 and between the first circuit group 110 and the second circuit group 120 may be that a circuit unit U4 of the second boundary circuit 122 needs to receive data outputted by a circuit unit U2 of the first boundary circuit 112 and a circuit unit U6 of the third boundary circuit 142 to perform circuit calculation.

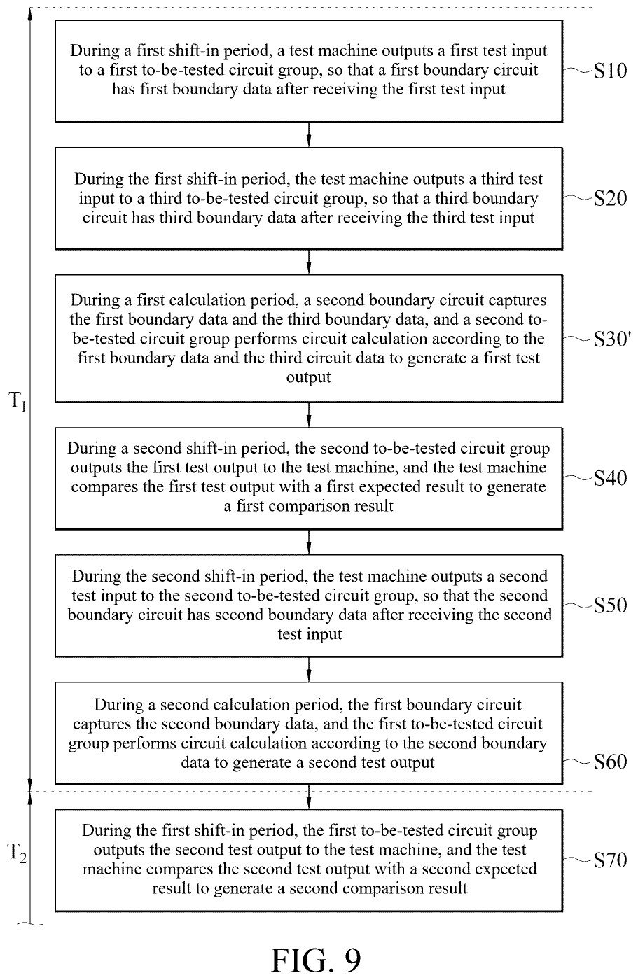

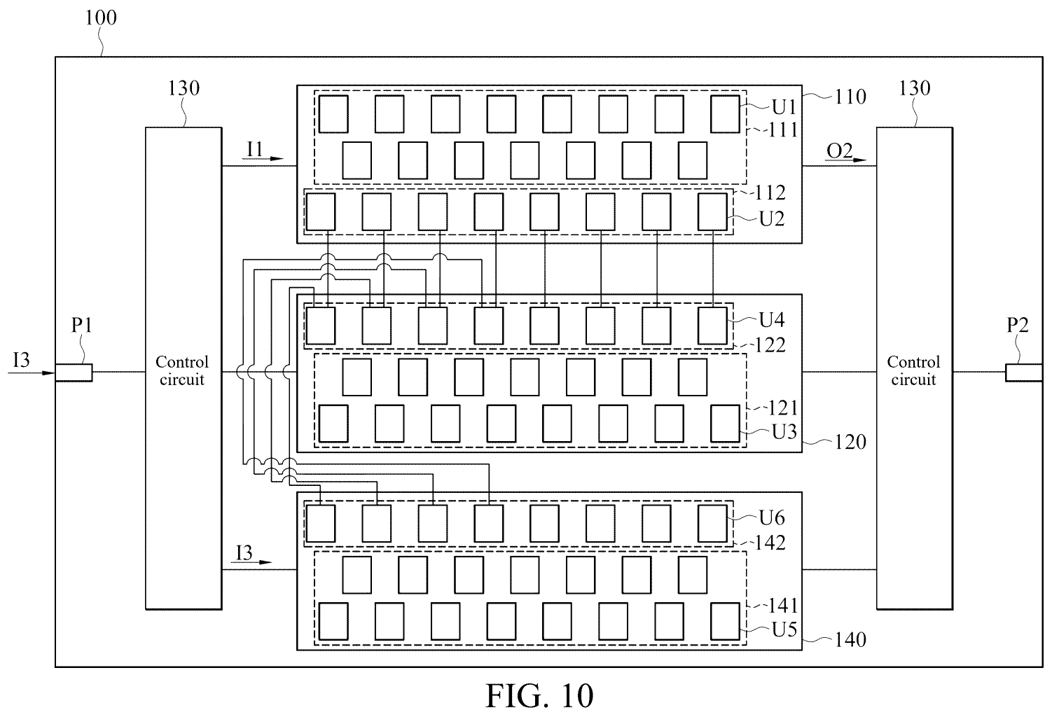

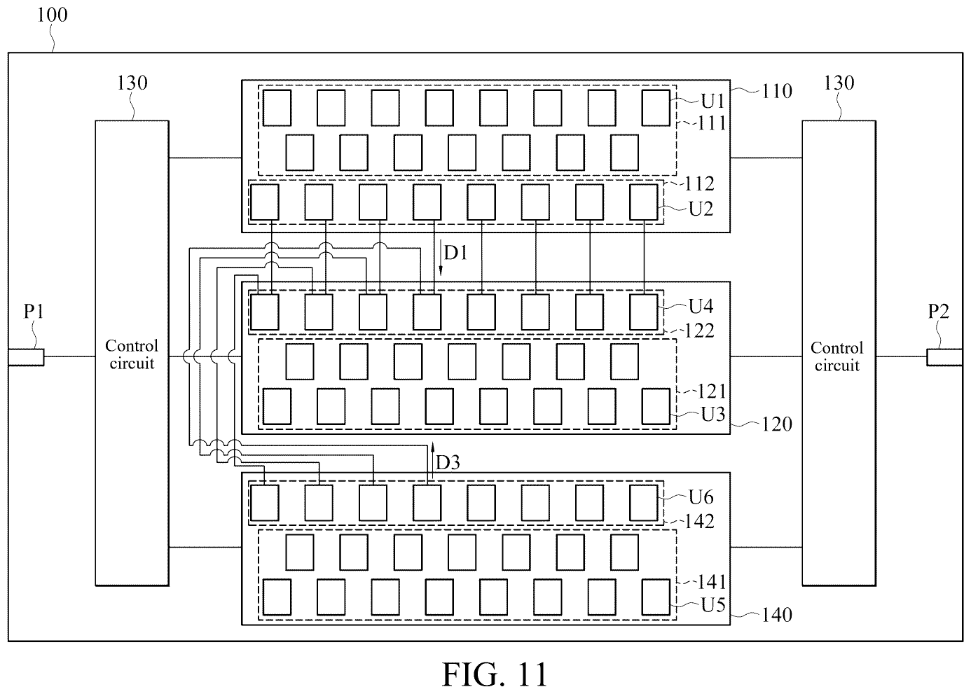

In some embodiments, the first shift-in period may be divided into a corresponding number of shift-in sessions according to the number of related circuit groups. FIG. 9 is a schematic flowchart of another embodiment of the boundary testing method. FIG. 10 is a schematic diagram of an example of the chip in FIG. 8 during a first shift-in session of a first shift-in period. FIG. 11 is a schematic diagram of an example of the chip in FIG. 8 during a first calculation period. Refer to FIG. 8 to FIG. 11. Using the second circuit group 120 related to two circuit groups (that is, the first circuit group 110 and the third circuit group 140) as an example, the first shift-in period is divided into two shift-in sessions (hereinafter respectively referred to a first shift-in session and a second shift-in session). The first shift-in session and the second shift-in session are connected in sequence.

During the first shift-in period, the test machine 200 of the boundary testing system 1 outputs the first test input I1 to the first circuit group 110 of the chip 100 during the first shift-in session (that is, step S10), and further outputs the third test input 13 to the third circuit group 140 of the chip 100 during the second shift-in session, so that the third boundary circuit 142 of the third circuit group 140 has third boundary data D3 after receiving the third test input 13 (step S20). In other words, during the first shift-in session of the first shift-in period, the first circuit group 110 receives the first test input I1, so that the first boundary circuit 112 has the first boundary data D1; and subsequently, during the second shift-in session of the first shift-in period, the third circuit group 140 receives the third test input 13, so that the third boundary circuit 142 has the third boundary data D3.

Specifically, as shown in FIG. 10, during the first shift-in session of the first shift-in period, the control circuit 130 of the chip 100 disconnects the second circuit group 120 from the test pin P1 and the third circuit group 140 from the test pin P1, and establishes the connection between the test pin P1 and the first circuit group 110. In addition, the control circuit 130 causes the second circuit group 120 and the third circuit group 140 to not operate, and causes the first circuit group 110 to operate, so that the test machine 200 provides the first test input I1 to the first circuit group 110 of the chip 100 through the test pin P1 of the chip 100, causing the first boundary circuit 112 of the first circuit group 110 to have the first boundary data D1. During the second shift-in session of the first shift-in period, the test machine 200 generates and outputs the third test input 13 to the test pin P1 of the chip 100, and then provides the third test input 13 to the third circuit group 140 of the chip 100 through the test pin P1. In other words, during the second shift-in session of the first shift-in period, the control circuit 130 of the chip 100 disconnects the first circuit group 110 from the test pin P1 and the second circuit group 120 from the test pin P1, and establishes the connection between the test pin P1 and the third circuit group 140. In addition, the control circuit 130 causes the first circuit group 110 and the second circuit group 120 to not operate, and causes the third circuit group 140 to operate, so that the third circuit group 140 may receive the third test input 13 through the test pin P1. After the third circuit group 140 receives the third test input 13, the third boundary circuit 142 has third boundary data D3. In this way, the third boundary data D3 refers to data subsequently outputted to the second boundary circuit 122 of the second circuit group 120, as shown in FIG. 11. In other words, the first shift-in session of the first shift-in period is a session when the first circuit group 110 operates, and the second shift-in session of the first shift-in period is a session when the third circuit group 140 operates.

In some embodiments, the first shift-in session and the second shift-in session of the first shift-in period may be set in sequence or in reverse order. In other words, in an example, step S10 may be performed first, and step S20 may be performed subsequently. In another example, step S20 may be performed first, and step S10 may be performed subsequently.

Subsequently, during the first shift-in period, during the first calculation period, the second boundary circuit 122 of the second circuit group 120 captures the first boundary data D1 of the first boundary circuit 112 and the third boundary data D3 of the third boundary circuit 142, and the second circuit group 120 performs circuit calculation according to the first boundary data D1 and the third boundary data D3 to generate the first test output O1 (step S30′).

Specifically, as shown in FIG. 11, after the related circuit groups of the second circuit group 120 have the boundary data (that is, the first boundary circuit 112 has the first boundary data D1 and the third boundary circuit 142 has the third boundary data D3), the first calculation period is subsequently entered, that is, step S30′ is performed. During the first calculation period, the control circuit 130 of the chip 100 causes the first circuit group 110 and the third circuit group 140 to not operate, and causes the second circuit group 120 to operate. In this way, the circuit unit U4 that needs the first boundary data D1 and the third boundary data D3 for circuit calculation in the second boundary circuit 122 of the second circuit group 120 captures the first boundary data D1 of the first boundary circuit 112 and the third boundary data D3 of the third boundary circuit 142, and the second main circuit 121 and the second boundary circuit 122 of the second circuit group 120 perform circuit calculation according to the currently saved data, the first boundary data D1, and the third boundary data D3 to generate the first test output O1. During the second shift-in period, the test machine 200 may determine whether functions of the second circuit group 120, the circuit unit U2 in the first boundary circuit 112 that outputs data to the second circuit group 120, and the circuit unit U6 in the third boundary circuit 142 that outputs data to the second circuit group 120 are normal by comparing whether the first test output O1 is consistent with the first expected result.

Similarly, during the second shift-in period and the second calculation period, the second boundary circuit 122 of the second circuit group 120 has the second boundary data D2 (step S50) according to the second test input 12 outputted by the test machine 200, and then the first circuit group 110 captures the second boundary data D2 of the second boundary circuit 122 through the first boundary circuit 112 and performs circuit calculation accordingly to generate the second test output O2 (step S60). Next, during the next shift-in period (for example, the first shift-in period of the next test cycle), the test machine 200 may determine whether functions of the first circuit group 110 and the circuit unit U4 in the second boundary circuit 122 that outputs data to the first circuit group 110 are normal by comparing whether the second test output O2 is consistent with the second expected result.

In some embodiments, during the second calculation period, before or after the first circuit group 110 generating the second test output O2 (step S60), the test machine 200 may further perform function detection on the third circuit group 140 and a related circuit group thereof. Specifically, during the second shift-in period, the third circuit group 140 captures the second boundary data D2 of the second boundary circuit 122 through the third boundary circuit 142 and performs circuit calculation accordingly to generate the third test output (not shown in the figure), and then outputs data to the test machine 200 during the next operation period. In this case, the test machine 200 may determine whether functions of the third circuit group 140 and the circuit unit U4 in the second boundary circuit 122 that outputs data to the third circuit group 140 are normal by comparing whether the third test output is consistent with a corresponding expected result (and the third expected result).

In some embodiments, the third circuit group 140 operates according to a third clock signal, and the control circuit 130 may cause the third circuit group 140 to not operate by stopping inputting the third clock signal to the third circuit group 140. In some embodiments, an on period (for example, a logic “1” period) of the first clock signal, an on period (for example, a logic “1” period) of the second clock signal, and an on period (for example, a logic “1” period) of the third clock signal may be mutually exclusive. In other words, when the first circuit group 110 operates (for example, during the first shift-in session and the second calculation period of the first shift-in period, that is, step S10 and step S60), the second circuit group 120 and the third circuit group 140 stop operation. When the second circuit group 120 operates (for example, during the first calculation period and the second shift-in period, that is, step S30′, step S40, and step S50), the first circuit group 110 and the third circuit group 140 stop operation. When the third circuit group 140 operates (for example, during the first shift-in period and the second shift-in session, that is, step S20), the first circuit group 110 and the second circuit group 120 stop operation.

In some embodiments, the first circuit group 110, the second circuit group 120, and the third circuit group 140 that stop operation maintain data before the stop.

It can be learned from the above embodiments that, during a function test process of the chip 100, during the shift-in period, a related circuit group (that is, a circuit group data-connected to a boundary circuit and a current circuit group) of a currently tested circuit group (hereinafter referred to as the current circuit group) receives a test input from an external input of the chip 100, so that the boundary circuit of the related circuit group has boundary data. During the subsequent calculation period, the current circuit group captures the boundary data of the related circuit group through the boundary circuit thereof and performs circuit calculation according to the captured boundary data to generate a test output. Then, during the next shift-in period, the current circuit group further outputs the generated test output to the test machine 200 outside the chip 100, so that the test machine 200 determines whether functions of the current circuit group and the related boundary circuit thereof (that is, a circuit unit in the boundary circuit of other circuit group that outputs the boundary data to the current circuit group) are normal according to the received test output and the corresponding expected result. In this way, the test machine 200 determines that functions of the circuit group and the related boundary circuit thereof are normal according to a comparison result that the test output is consistent with the corresponding expected result. Otherwise, the test machine 200 determines that functions of the current circuit group and the related boundary circuit thereof are abnormal according to a comparison result that the test output is inconsistent with the corresponding expected result.

In summary, in the chip 100, the boundary testing system 1, and the boundary testing method according to any one of the embodiments, each boundary circuit 112/122/142 is tested by dynamically switching the circuit connection to select one of the circuit groups 110, 120, 140 as currently-tested circuit. In this way, there is no need to add an additional circuit for testing the boundary circuits 112, 122/112, 122, 142, and there is also no need to spend time selecting the boundary circuit 112/122/142 to be currently tested from the circuit groups 110, 120/110,120,140. In addition, in the chip 100, the boundary testing system 1, and the boundary testing method according to any one of the embodiments, all circuit units U1 to U6 inside the chip 100 can operate according to an original grouping manner, while maintaining a testing relationship between the circuit groups 110, 120/110, 120, 140.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A chip with boundary testing, comprising:
a first circuit group, comprising:
a first main circuit; and
a first boundary circuit, coupled to the first main circuit; and
a second circuit group, comprising:
a second main circuit; and
a second boundary circuit, coupled to the second main circuit and the first boundary circuit;
wherein during a first shift-in period, the first circuit group receives a first test input, and the first boundary circuit has first boundary data after the first circuit group receives the first test input;
wherein during a first calculation period after the first shift-in period, the second boundary circuit captures the first boundary data, and the second circuit group performs a circuit calculation according to the first boundary data to generate a first test output; and
wherein during a second shift-in period after the first calculation period, the second main circuit outputs the first test output.

2. The chip according to claim 1, further comprising:
at least one test pin, configured to connect to an external test machine, wherein the first circuit group receives the first test input from the test machine via at least one of the at least one test pin, the second main circuit outputs the first test output to the test machine via remaining of the at least one test pin, and the test machine compares the first test output with a first expected result to generate a first comparison result.

3. The chip according to claim 1, wherein the second circuit group is further configured to, during the second shift-in period, receive a second test input, so that the second boundary circuit has second boundary data.

4. The chip according to claim 3, wherein the first boundary circuit is configured to capture the second boundary data during a second calculation period after the second shift-in period, the first circuit group is further configured to perform a circuit calculation according to the second boundary data to generate a second test output during the second calculation period, and the first main circuit is further configured to output the second test output during the first shift-in period.

5. The chip according to claim 4, further comprising:
at least one test pin, configured to connect to an external test machine, wherein the second test input is from the test machine, the first main circuit outputs the second test output to the test machine, and the test machine compares the second test output with a second expected result to generate a second comparison result.

6. The chip according to claim 4, wherein during the first shift-in period and the second calculation period, the second circuit group does not operate, and during the first calculation period and the second shift-in period, the first circuit group does not operate.

7. The chip according to claim 1, further comprising:
a third circuit group, comprising:
a third main circuit; and
a third boundary circuit, coupled to the third main circuit and the second boundary circuit
wherein during the first shift-in period, the third circuit group receives a third test input, and the third boundary circuit has third boundary data after the first circuit group receives the third test input; and
wherein during the first calculation period, the second boundary circuit further captures the third boundary data, and the second circuit group performs the circuit calculation according to the first boundary data and the third boundary data to generate the first test output.

8. The chip according to claim 7, wherein the first circuit group does not operate during a session when the third circuit group operates during the first shift-in period, the first calculation period, and the second shift-in period after the first calculation period, the second circuit group does not operate during the first shift-in period and a second calculation period after the second shift-in period, and the third circuit group does not operate during a session when the first circuit group operates during the first shift-in period, the first calculation period, and the second shift-in period.

9. The chip according to claim 1, wherein the second circuit group is further configured to receive a second test input during a pre-shift-in period before the first calculation period.

10. A boundary testing system, comprising:
a chip, comprising:
a first circuit group, comprising:
a first main circuit; and
a first boundary circuit, coupled to the first main circuit; and
a second circuit group, comprising:
a second main circuit; and
a second boundary circuit, coupled to the second main circuit and the first boundary circuit; and
a test machine, coupled to the chip;
wherein during a first shift-in period, the test machine outputs a first test input to the first circuit group, so that the first boundary circuit has first boundary data after the first circuit group receives the first test input;
wherein during a first calculation period after the first shift-in period, the second boundary circuit captures the first boundary data from the first boundary circuit, and the second circuit group performs a circuit calculation according to the captured first boundary data to generate a first test output; and
wherein during a second shift-in period after the first calculation period, the second main circuit outputs the first test output to the test machine, and the test machine compares the first test output with a first expected result to generate a first comparison result.

11. The boundary testing system according to claim 10, wherein during the second shift-in period, the test machine is further configured to output a second test input to the second circuit group, so that after the second circuit group receives the second test input, the second boundary circuit has second boundary data.

12. The boundary testing system according to claim 11, wherein the first boundary circuit is configured to captures the second boundary data during a second calculation period after the second shift-in period, and the first circuit group is configured to, during the second calculation period, perform a circuit calculation according to the second boundary data to generate a second test output to the test machine, and the test machine is further configured to compare the second test output with a second expected result to generate a second comparison result.

13. The boundary testing system according to claim 10, wherein the chip further comprises:
a third circuit group, comprising:
a third main circuit; and
a third boundary circuit, coupled to the third main circuit and the second boundary circuit, wherein
wherein during the first shift-in period, the test machine further outputs a third test input to the third circuit group, so that after the third circuit group receives the third test input, the third boundary circuit has third boundary data, and
wherein during the first calculation period, the second boundary circuit further captures the third boundary, data and the second circuit group performs the circuit calculation according to the first boundary data and the third boundary data to generate the first test output.

14. The boundary testing system according to claim 10, wherein the test machine is further configured to output a second test input to the second circuit group during a pre-shift-in period before the first calculation period.

15. A boundary testing method applicable to a chip, comprising:
during a first shift-in period, outputting a first test input to a first circuit group of the chip, so that a first boundary circuit of the first circuit group has first boundary data after receiving the first test input;
during a first calculation period after the first shift-in period, capturing the first boundary data by a second boundary circuit of a second circuit group of the chip, and performing a circuit calculation according to the first boundary data by a second main circuit and the second boundary circuit of the second circuit group to generate a first test output, wherein the second main circuit is coupled to the second boundary circuit; and
during a second shift-in period after the first calculation period, outputting the first test output by the second main circuit, and comparing the first test output with a first expected result to generate a first comparison result.

16. The boundary testing method according to claim 15, further comprising:
during the second shift-in period, inputting a second test input to the second circuit group, so that the second boundary circuit has second boundary data.

17. The boundary testing method according to claim 16, further comprising:
during a second calculation period after the second shift-in period, capturing the second boundary data by the first boundary circuit, and performing circuit calculation according to the second boundary data by a first main circuit and the first boundary circuit of the first circuit group to generate a second test output, wherein the first main circuit is coupled to the first boundary circuit; and
during the first shift-in period, outputting the second test output by the first main circuit, and comparing the second test output with a second expected result to generate a second comparison result.

18. The boundary testing method according to claim 17, further comprising:
during the first shift-in period and the second calculation period, causing the second circuit group to not operate; and
during the first calculation period and the second shift-in period, causing the first circuit group to not operate.

19. The boundary testing method according to claim 15, further comprising:
during the first shift-in period, inputting a third test input to a third circuit group of the chip, so that a third boundary circuit of the third circuit group has third boundary data after receiving the third test input; and
during the first calculation period, capturing the third boundary data by the second boundary circuit;
wherein in the step of performing the circuit calculation according to the first boundary data to generate the first test output, the circuit calculation is performed according to the first boundary data and the third boundary data.

20. The boundary testing method according to claim 19, further comprising:
during the first calculation period and a second shift-in period after the first calculation period, causing the first circuit group and the third circuit group to not operate;
during a session when the first circuit group operates during the first shift-in period and a second calculation period after the second shift-in period, causing the second circuit group and the third circuit group to not operate; and
during a session when the third circuit group operates during the first shift-in period, causing the first circuit group and the second circuit group to not operate.
